(19) United States
(12) Patent Application Publication
(10) Pub. No.: US 2020/0266279 A1
(43) Pub. Date: Aug. 20, 2020

(54) SEMICONDUCTOR DEVICE

(71) Applicants: KABUSHIKI KAISHA TOSHIBA, Minato-ku (JP); Toshiba Electronic Devices & Storage Corporation, Minato-ku (JP)

(72) Inventors: Masataka INO, Oita (JP); Hiroaki KATOU, Nonoichi (JP)

(73) Assignees: KABUSHIKI KAISHA TOSHIBA, Minato-ku (JP); Toshiba Electronic Devices & Storage Corporation, Minato-ku (JP)

(21) Appl. No.: 16/422,318

(22) Filed: May 24, 2019

(30) Foreign Application Priority Data
Feb. 19, 2019 (JP) 2019-027493

(51) Int. Cl. H01L 29/40; H01L 29/06; H01L 29/417; H01L 29/78; H01L 29/423; H01L 29/66

(52) U.S. Cl. CPC H01L 29/407; H01L 29/0696; H01L 29/41741; H01L 29/66734; H01L 29/4238; H01L 29/4236; H01L 29/401; H01L 29/7813

(57) ABSTRACT

According to an embodiment, a semiconductor device includes a first electrode, a first semiconductor region, a second semiconductor region, a third semiconductor region, a gate electrode, a first conductive layer, and a second electrode. The gate electrode opposes, with a gate insulating portion interposed, a portion of the first semiconductor region, the second semiconductor region, and the third semiconductor region in a first direction. The first direction is perpendicular to a second direction. The second direction is from the first semiconductor region toward the second semiconductor region. The first conductive layer is provided inside the first semiconductor region with a first insulating layer interposed. Another portion of the first semiconductor region is provided between the first conductive layer and the second semiconductor region and between the first conductive layer and the gate electrode.

### CROSS-REFERENCE TO RELATED APPLICATIONS

This application is based upon and claims the benefit of priority from Japanese Patent Application No. 2019-027493, filed on Feb. 19, 2019; the entire contents of which are incorporated herein by reference.

### FIELD

Embodiments described herein relate generally to a semiconductor device.

### BACKGROUND

A semiconductor device such as MOSFET (metal-oxide-semiconductor field-effect transistors) is used for applications such as power conversion. The ON-resistance of the semiconductor device is desirably low.

### BRIEF DESCRIPTION OF THE DRAWINGS

FIG. 1 is a plan view showing a semiconductor device according to an embodiment;

FIG. 2 and FIG. 3 are plan views showing a portion of the semiconductor device according to the embodiment;

FIG. 4 is a cross-sectional view along line IV-IV of FIG. 2 and FIG. 3;

FIG. 5 is a cross-sectional view along line V-V of FIG. 2 and FIG. 3;

FIG. 6A to FIG. 6C, FIG. 7A to FIG. 7C, and FIG. 8A to FIG. 8C are sectional views showing manufacturing processes of the semiconductor device according to the embodiment;

FIG. 9 is a cross-sectional view showing a portion of a semiconductor device according to a reference example;

FIG. 10 is a cross-sectional view showing a portion of a semiconductor device according to a first modification of the embodiment;

FIG. 11 is a plan view showing a portion of a semiconductor device according to a second modification of the embodiment;

FIG. 12 is a perspective cross-sectional view including the XII-XII cross section of FIG. 11;

FIG. 13 is a cross-sectional view showing a portion of a semiconductor device according to a third modification of the embodiment; and

FIG. 14A is an example of a plan view including the XIV-XIV line cross section of FIG. 13 and FIG. 14B is another example of a plan view including the XIV-XIV cross section of FIG. 13.

### DETAILED DESCRIPTION

According to an embodiment, a semiconductor device includes a first electrode, a first semiconductor region, a second semiconductor region, a third semiconductor region, a gate electrode, a first conductive layer, and a second electrode. The first semiconductor region is provided on the first electrode and electrically connected to the first electrode. The first semiconductor region is of a first conductivity type. The second semiconductor region is provided on the first semiconductor region. The second semiconductor region is of a second conductivity type. The third semiconductor region is selectively provided on the second semiconductor region. The third semiconductor region is of the first conductivity type. The gate electrode opposes, with a gate insulating portion interposed, a portion of the first semiconductor region, the second semiconductor region, and the third semiconductor region in a first direction. The first direction is perpendicular to a second direction. The second direction is from the first semiconductor region toward the second semiconductor region. The first conductive layer is provided inside the first semiconductor region with a first insulating layer interposed. Another portion of the first semiconductor region is provided between the first conductive layer and the second semiconductor region and between the first conductive layer and the gate electrode. The second electrode is provided on the second semiconductor region, the third semiconductor region, and the gate electrode. The second electrode is electrically connected to the second semiconductor region, the third semiconductor region, and the first conductive layer.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

In the following descriptions and drawings, notations of n⁺, n⁻ and p represent relative heights of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative height of a net impurity concentration after mutual compensation of these impurities when respective regions include both of a p-type impurity and an n-type impurity.

The embodiments described below may be implemented by reversing the p-type and the n-type of the semiconductor regions.

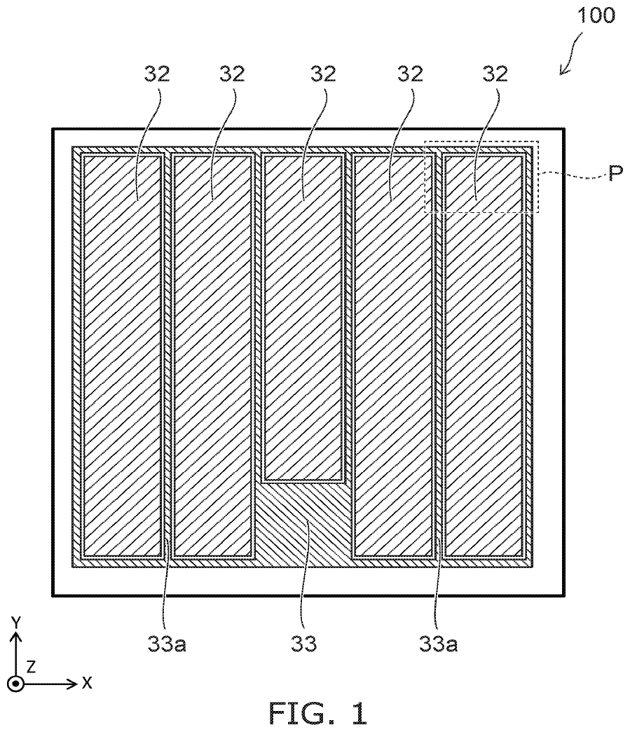

FIG. 1 is a plan view showing a semiconductor device according to the embodiment.

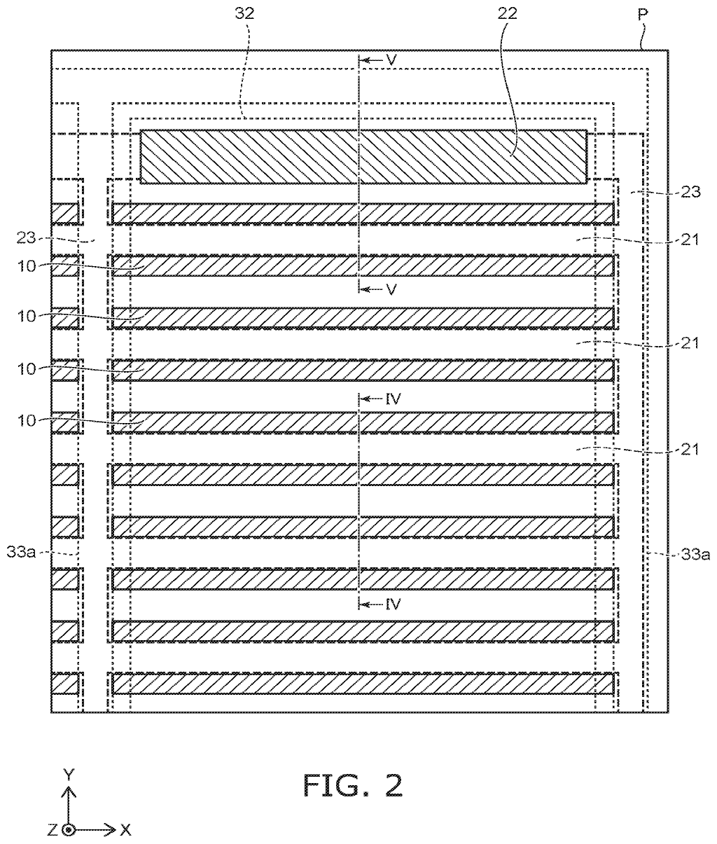

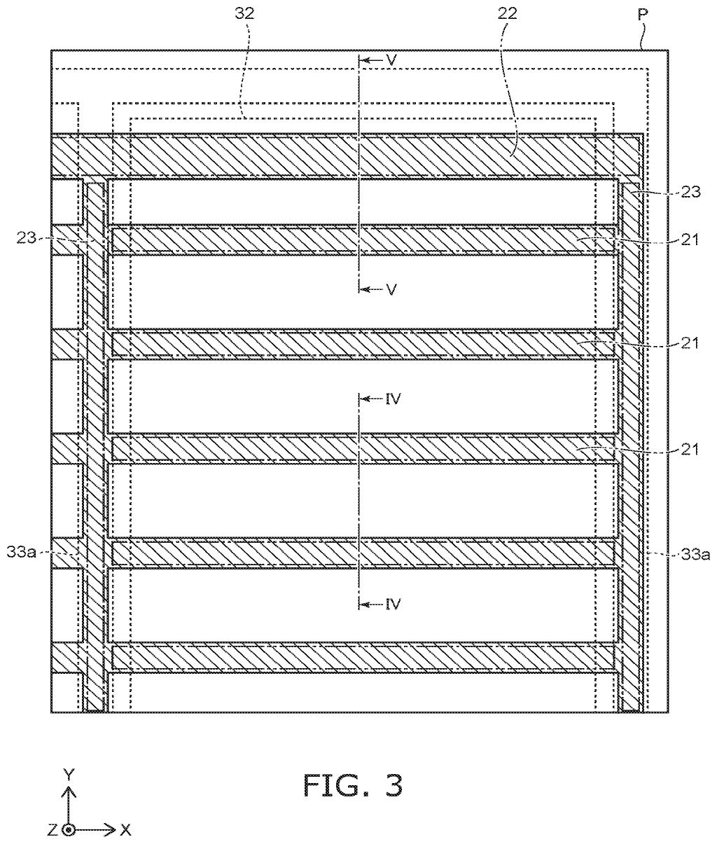

FIG. 2 and FIG. 3 are plan views showing a portion of the semiconductor device according to the embodiment.

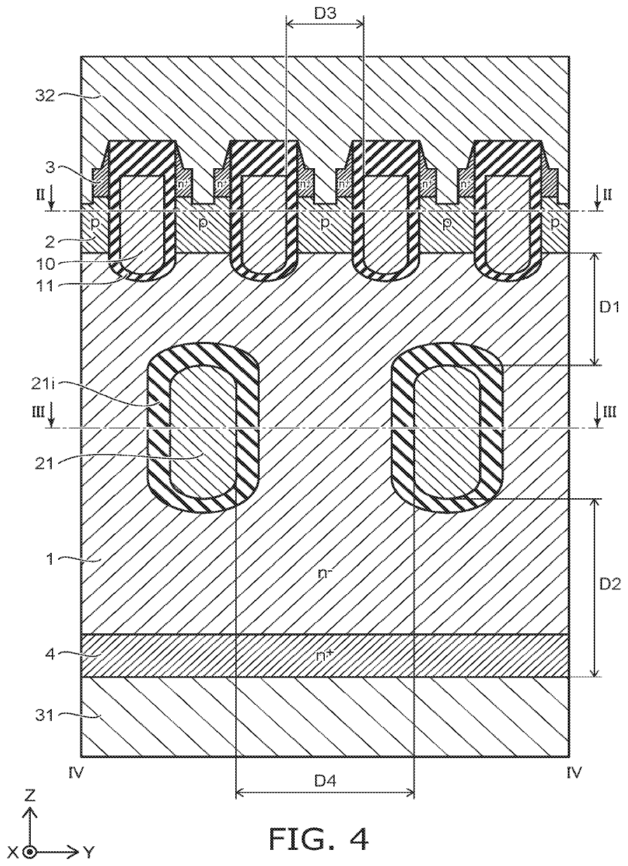

FIG. 4 is a cross-sectional view along line IV-IV of FIG. 2 and FIG. 3.

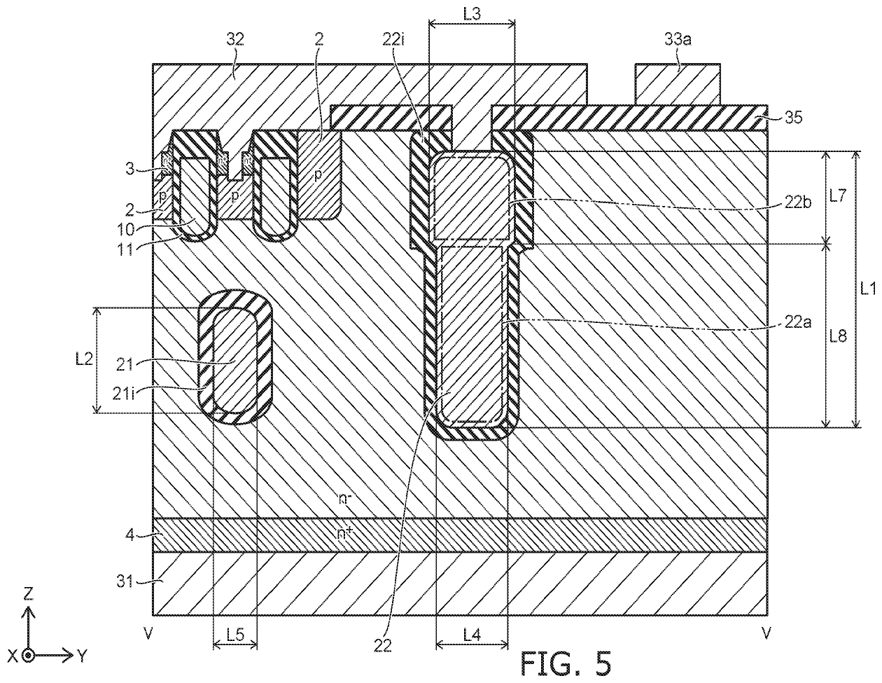

FIG. 5 is a cross-sectional view along line V-V of FIG. 2 and FIG. 3.

As shown in FIG. 4 and FIG. 5, the semiconductor device 100 according to the embodiment includes an n⁻-type (a first conductivity type) semiconductor region 1 (a first semiconductor region), a p-type (second conductivity type) base region 2 (a second semiconductor region), an n⁺-type source region 3 (a third semiconductor region), an n⁺-type buffer region 4, a gate electrode 10, a first conductive layer 21, a second conductive layer 22, a drain electrode 31 (a first electrode), and a source electrode 32 (a second electrode). The semiconductor device 100 is MOSFET.

An XYZ orthogonal coordinate system is used in the description of the embodiments hereinafter. A direction from the drain electrode 31 toward the n⁻-type semiconductor region 1 is taken as a Z-direction (a second direction). Two mutually-orthogonal directions perpendicular to the Z-direction are taken as an X-direction (a third direction) and a Y-direction (a first direction). For the description, the direction from the drain electrode 31 toward the n⁻-type semiconductor region 1 is called “up;” and the reverse direction is called “down.” These directions are based on the relative positional relationship between the drain electrode 31 and the n⁻-type semiconductor region 1 and are independent of the direction of gravity.

As shown in FIG. 4, the drain electrode 31 is provided on the lower surface of the semiconductor device 100. The n⁺-type buffer region 4 is provided on the drain electrode 31 and is electrically connected to the drain electrode 31. The n⁻-type semiconductor region 1 is provided on the n⁺-type buffer region 4.

The first conductive layer 21 is provided inside the n⁻-type semiconductor region 1 with a first insulating layer 21i interposed. The p-type base region 2 is provided on the n⁻-type semiconductor region 1. The n⁺-type source region 3 is selectively provided on the p-type base region 2. The gate electrode 10 is opposed to, with a gate insulating layer 11 interposed, in the Y-direction a portion of the n⁻-type semiconductor region 1, p-type base region 2, and n⁺-type source region 3.

Another portion of the n⁻-type semiconductor region 1 is provided between the first conductive layer 21 and the p-type base region 2 and between the first conductive layer 21 and the gate electrode 10. The upper end of the first conductive layer 21 is located below the lower end of the gate electrode 10. For example, a distance D1 in the Z-direction between the first conductive layer 21 and the p-type base region 2 is shorter than a distance D2 in the Z-direction between the first conductive layer 21 and the drain electrode 31.

The source electrode 32 is provided on the p-type base region 2, the n⁺-type source region 3, and the gate electrode 10. The source electrode 32 is electrically connected to the p-type base region 2, the n⁺-type source region 3, and the first conductive layer 21. In the example of FIG. 4, a portion of the source electrode 32 is opposed to the n⁺-type source region 3 and a portion of the p-type base region 2 in the Y-direction. The source electrode 32 is electrically separated from the gate electrode 10.

For example, the p-type base region 2, the n⁺-type source region 3, the gate electrode 10, and the first conductive layer 21 each are multiply provided along the Y-direction. For example, a distance D3 between the adjacent gate electrodes 10 is shorter than a distance D4 between the adjacent first conductive layers 21.

As shown in FIG. 5, the second conductive layer 22 is provided inside the n⁻-type semiconductor region 1 with a second insulating layer 22i interposed. The second conductive layer 22 is separated from the first conductive layer 21 in the Y-direction. The second conductive layer 22 is electrically connected to the first conductive layer 21 via a third conductive layer 23 shown in FIG. 2. The upper end of the second conductive layer 22 is in contact with the source electrode 32. The first conductive layer 21 is electrically connected to the source electrode 32 via the second conductive layer 22 and the third conductive layer 23.

A portion of the n⁻-type semiconductor region 1 located around the second conductive layer 22 is covered by an insulating layer 35. A portion of the source electrode 32 extends through the insulating layer 35 and the second insulating layer 22i and is in contact with the upper end of the second conductive layer 22.

A length L1 in the Z-direction of the second conductive layer 22 is longer than a length L2 in the Z-direction of the first conductive layer 21. The upper end of the second conductive layer 22 is located above the upper end of the first conductive layer 21. For example, the lower end of the second conductive layer 22 is located below the lower end of the first conductive layer 21.

The second conductive layer 22 includes a first conductive portion 22a and a second conductive portion 22b. The second conductive portion 22b is provided on the first conductive portion 22a. A length L3 in the Y-direction of the second conductive portion 22b is longer than a length L4 in the Y-direction of the first conductive portion 22a. For example, the length L4 in the Y-direction of the first conductive portion 22a is longer than a length L5 in the Y-direction of the first conductive layer 21. For example, a length L7 in the Z-direction of the second conductive portion 22b is shorter than a length L8 in the Z-direction of the first conductive portion 22a.

As shown in FIG. 1, the source electrode 32 and a gate pad 33 are provided on the upper surface of the semiconductor device 100. The source electrode 32 and the gate pad 33 are separated from each other. For example, a plurality of source electrodes 32 are arranged in the X-direction. A wiring portion 33a that surrounds each source electrode 32 along the X-Y plane is connected to the gate pad 33.

FIG. 2 is a plan view of a portion P of FIG. 1 and corresponds to the cross-sectional view along line II-II of FIG. 4. FIG. 3 is a plan view of the portion P of FIG. 1 and corresponds to the cross-sectional view along line III-III of FIG. 4. In FIG. 2, the first conductive layer 21, the third conductive layer 23, the source electrode 32, and the wiring portion 33a are represented by broken lines. In FIG. 3, the source electrode 32 and the wiring portion 33a are represented by broken lines. Further, in FIG. 2 and FIG. 3, the n⁻-type semiconductor region 1, the p-type base region 2, the n⁺-type source region 3, the gate insulating layer 11, the first insulating layer 21i, and the second insulating layer 22i are omitted.

A plurality of gate electrodes 10 and a plurality of first conductive layers 21 are arranged in the Y-direction below the source electrode 32. The end in the X-direction of each gate electrode 10 is pulled up to the upper surface of the semiconductor device 100, and is connected to the wiring portion 33a.

As shown in FIG. 2 and FIG. 3, the semiconductor device 100 further includes a third conductive layer 23 extending along the Y-direction. The third conductive layer 23 is provided inside the n⁻-type semiconductor region 1 with an insulating layer interposed (not shown). The first conductive layers 21 are separated from the second conductive layer 22 in the Y-direction. The end in the X-direction of each first conductive layer 21 is connected to the third conductive layer 23. The end in the Y-direction of the third conductive layer 23 is connected to the second conductive layer 22.

For example, a position in the X-direction of at least a portion of the third conductive layer 23 is the same as a position in the X-direction of at least a portion of the wiring portion 33a. In other words, at least a portion of the third conductive layer 23 is located directly below the wiring portion 33a. Or, the position in the X-direction of the third conductive layer 23 may be different from the position in the X-direction of the wiring portion 33a.

The operation of the semiconductor device 100 will be described.

In a state where a positive voltage is applied to the drain electrode 31 with respect to the source electrode 32, a voltage higher than a threshold is applied to the gate electrode 10. Thereby, a channel (an inversion layer) is formed in the p-type base region 2, and the semiconductor device 100 is set to the ON-state. The electrons flow from the source electrode 32 to the drain electrode 31 through the channel. When the voltage applied to the gate electrode 10 becomes lower than the threshold, the channel of the p-type base region 2 disappears, and the semiconductor device 100 is set to OFF-state.

When the semiconductor device 100 is switched to the OFF-state, the positive voltage applied to the drain electrode 31 with respect to the source electrode 32 increases. At this time, a depletion layer spreads from the interface between the first insulating layer 21i and the n⁻-type semiconductor region 1 toward the n⁻-type semiconductor region 1. The breakdown voltage of the semiconductor device 100 can be increased by the spread of the depletion layer. Or, an n-type impurity concentration in the n⁻-type semiconductor region 1 can be increased while maintaining the breakdown voltage of the semiconductor device 100; and the ON-resistance of the semiconductor device 100 can be reduced.

An example of the material of each component of the semiconductor device 100 will be described.

The n⁻-type semiconductor region 1, the p-type base region 2, the n⁺-type source region 3, and the n⁺-type buffer region 4 include silicon, silicon carbide, gallium nitride, or gallium arsenide as a semiconductor material. When silicon is used as the semiconductor material, arsenic, phosphorus, or antimony can be used as the n-type impurity. Boron can be used as the p-type impurity.

The gate electrode 10, the first conductive layer 21, the second conductive layer 22, and the third conductive layer 23 include a conductive material such as polysilicon.

The gate insulating layer 11, the first insulating layer 21i, the second insulating layer 22i, and the insulating layer 35 include an insulating material such as silicon oxide.

The drain electrode 31 and the source electrode 32 include metal such as aluminum, titanium, tungsten, or the like.

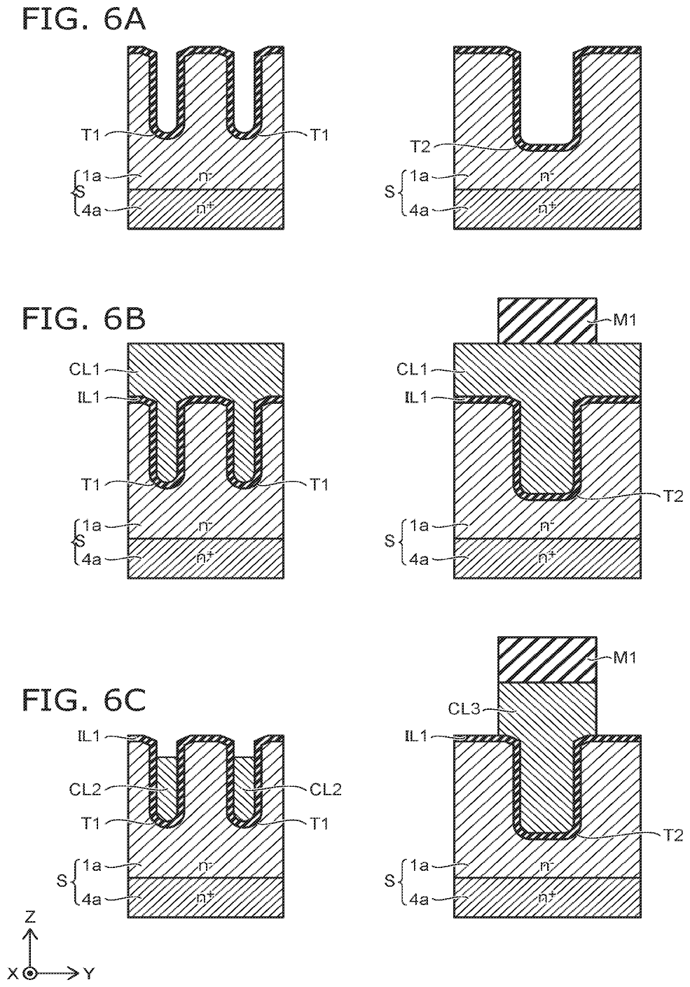

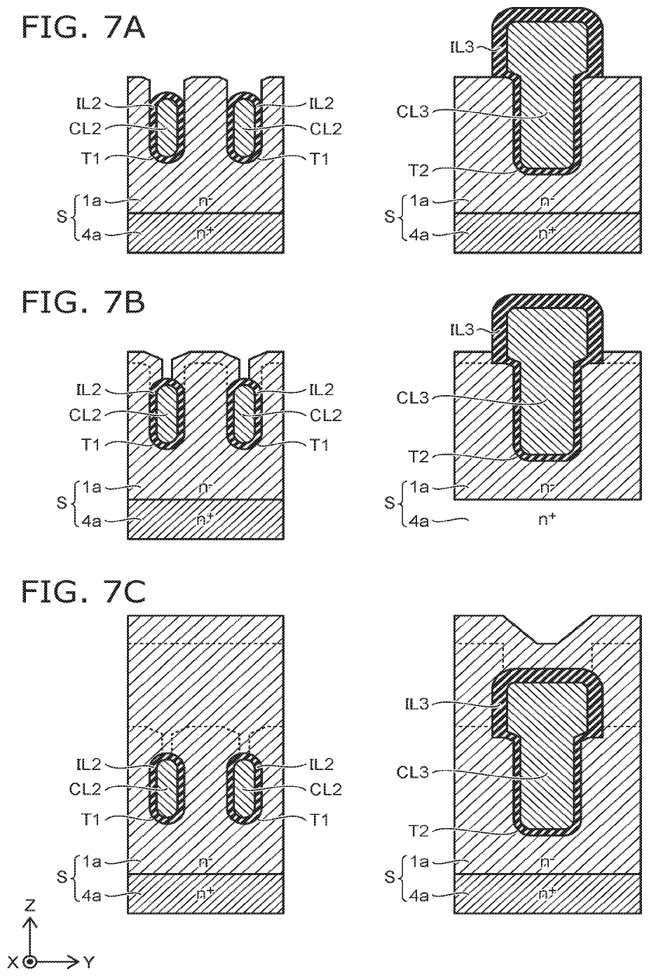

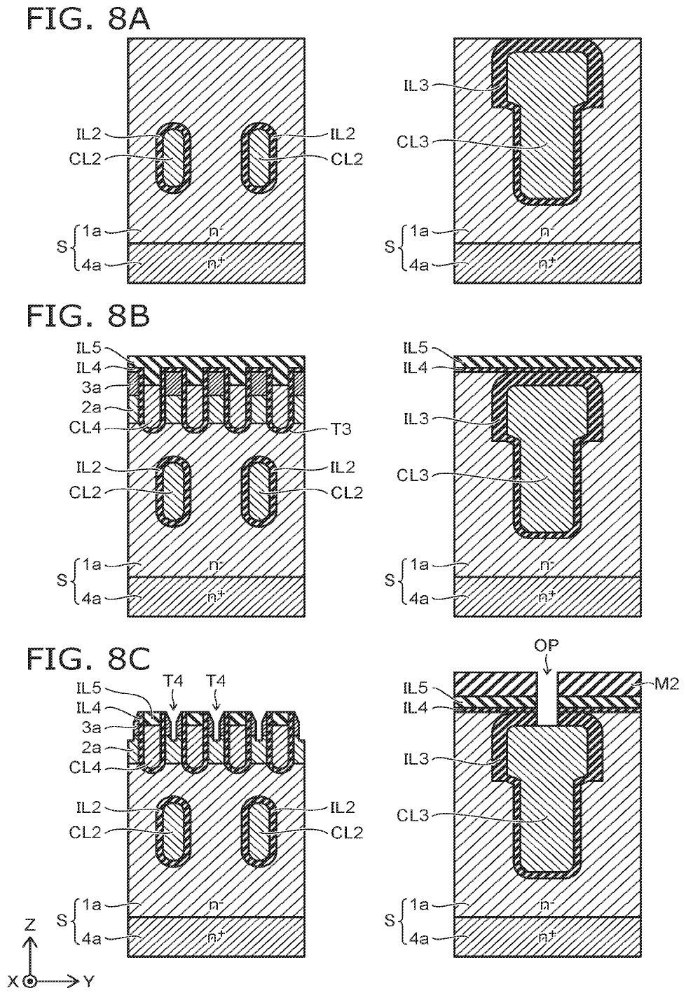

FIG. 6A to FIG. 6C, FIG. 7A to FIG. 7C, and FIG. 8A to FIG. 8C are sectional views showing manufacturing processes of the semiconductor device according to the embodiment.

The manufacturing method of the semiconductor device according to the embodiment will be described with reference to FIG. 6A to FIG. 8C. In FIG. 6A to FIG. 8C, the drawings on the left represent the manufacturing processes on a portion along line IV-IV of FIG. 2. The drawings on the right represent the manufacturing processes on a portion along line V-V of FIG. 2.

A semiconductor substrate S including an n⁺-type semiconductor region 4a and an n⁻-type semiconductor region 1a is prepared. The n⁻-type semiconductor region 1a is provided on the n⁺-type semiconductor region 4a. As shown in FIG. 6A, a plurality of trenches T1 and a trench T2 are formed on the upper surface of the n⁻-type semiconductor region 1a by, for example, reactive ion etching (RIE). For example, a width (a dimension in the Y-direction) of the trench T2 is wider than a width of the trench T1. A depth (a dimension in the Z-direction) of the trench T2 is deeper than a depth of the trench T1.

By thermal oxidation of the semiconductor substrate S, the insulating layer IL1 is formed on the surface of the n⁻-type semiconductor region 1a including the inner walls of the trenches T1 and the trench T2. The conductive layer CL1 is formed on the insulating layer IL1. The trenches T1 and the trench T2 are filled with the conductive layer CL1. As shown in FIG. 6B, the mask M1 is formed on a portion of the conductive layer CL1. The mask M1 is located above the trench T2.

As shown in FIG. 6C, a portion of the conductive layer CL1 not covered by the mask M1 is removed by RIE or wet etching. Thus, the conductive layer CL1 is divided into a plurality; and a plurality of conductive layers CL2 and a conductive layer CL3 are formed. The conductive layers CL2 are respectively provided inside the trenches T1. The conductive layer CL3 is provided inside the trench T2 and on the trench T2. A width of the mask M1 is wider than a width of the trench T2. Therefore, a width of the upper portion of the conductive layer CL3 is wider than a width of the lower portion of the conductive layer CL3.

Mask M1 is removed. The semiconductor substrate S is thermally oxidized to form an insulating layer on the surfaces of the conductive layers CL2 and the conductive layer CL3. A portion of the insulating layer IL1 provided on a portion of the surface of the n⁻-type semiconductor region 1a is removed. Thereby, as shown in FIG. 7A, a plurality of insulating layers IL2 respectively surrounding the conductive layers CL2 are formed. An insulating layer IL3 surrounding the conductive layer CL3 is formed.

A semiconductor material is selectively grown on the surface of the exposed n⁻-type semiconductor region 1a by metal organic vapor phase epitaxy (MOVPE). N-type impurities are added to the semiconductor material to be grown. An n-type impurity concentration of the added n-type impurities is substantially the same as an n-type impurity concentration in the n⁻-type semiconductor region 1a. By the MOVPE, through the process shown in FIG. 7B, the n⁻-type semiconductor region 1a becomes thicker. In FIG. 7B and FIG. 7C, a position where the surface of the n⁻-type semiconductor region 1a was present is indicated by a broken line. Each trench T1 is filled with the grown semiconductor material.

The upper surface of the n⁻-type semiconductor region 1a is caused to recede by chemical mechanical polishing (CMP). In the CMP, the insulating layer IL3 covering the conductive layer CL3 functions as a stopper. Therefore, a position of the upper surface of the n⁻-type semiconductor region 1a becomes substantially the same as a position of the upper end of the insulating layer IL3 as shown in FIG. 8A.

A plurality of trenches T3 are formed on the conductive layers CL2. By thermal oxidation, an insulating layer IL4 is formed along the surface of the n⁻-type semiconductor region 1a including the inner wall of each trench T3. A plurality of conductive layers CL4 are respectively formed inside the trenches T3. P-type impurities and n-type impurities are sequentially ion-implanted into n⁻-type semiconductor region 1a between adjacent trenches T3 to form a p-type semiconductor region 2a and an n⁺-type semiconductor region 3a. As shown in FIG. 8B, an insulating layer IL5 is formed on the conductive layers CL4 and the n⁺-type semiconductor regions 3a.

A mask M2 is formed on the insulating layer IL5. The mask M2 is not provided on the n⁺-type semiconductor regions 3a and the conductive layers CL4. The mask M2 is provided on the conductive layer CL3 and on the n⁻-type semiconductor regions 1a around the conductive layer CL3. The mask M2 has an opening OP. The opening OP is located on a portion of the conductive layer CL3. Chemical Dry Etching (CDE) or wet etching is performed using the mask M2 until the n⁺-type semiconductor regions 3a and a portion of the conductive layer CL3 are exposed. Thereby, a portion of the insulating layer IL3, a portion of the insulating layer IL4, and a portion of the insulating layer IL5 are removed. As shown in FIG. 8C, a portion of each n⁺-type semiconductor region 3a and the portion of each p-type semiconductor region 2a are removed to form a plurality of trenches T4. The bottom of the trench T4 is located in the p-type semiconductor region 2a.

A metal layer is formed to fill the trenches T4. The metal layer is patterned to form the source electrode 32, the gate pad 33, and the wiring portion 33a. The lower surface of the n⁺-type semiconductor region 4a is polished until the n⁺-type semiconductor region 4a has a prescribed thickness. The drain electrode 31 is formed on the polished lower surface of the n⁺-type semiconductor region 4a. Thus, the semiconductor device 100 according to the embodiment is manufactured.

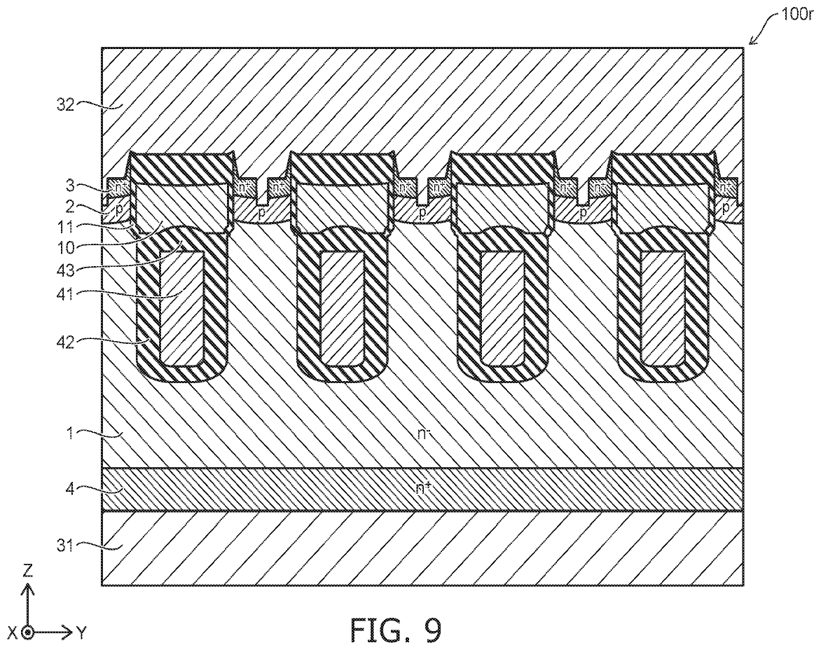

The effects of the embodiment will be described with reference to FIG. 9.

FIG. 9 is a cross-sectional view showing a portion of a semiconductor device according to a reference example.

The semiconductor device 100r shown in FIG. 9 includes a conductive layer 41. The conductive layer 41 is provided inside the n⁻-type semiconductor region 1 with the insulating layer 42 interposed. The gate electrode 10 is provided on the conductive layer 41 with the insulating layer 43 interposed. According to the structure shown in FIG. 9, the breakdown voltage of the semiconductor device 100r can be improved by the function of the conductive layer 41. Or, while maintaining the breakdown voltage of the semiconductor device 100r, an n-type impurity concentration in the n⁻-type semiconductor region 1 can be increased to reduce the ON-resistance of the semiconductor device 100r.

When a positive voltage is applied to the drain electrode 31 with respect to the source electrode 32, a large voltage is applied between the conductive layer 41 and the n⁻-type semiconductor region 1. In order to suppress dielectric breakdown, it is desirable that a thickness of the insulating layer 42 is large. On the other hand, a thickness of the gate insulating layer 11 is desirably smaller than the thickness of the insulating layer 42 in order to reduce the electrical resistance at the channel.

In the structure shown in FIG. 9, one conductive layer 41 is aligned with one gate electrode 10 in the Z-direction. Therefore, when the insulating layer 42 is formed thick, a width of the gate electrode 10 becomes wider accordingly. As the width of the gate electrode 10 increases, a number of the gate electrodes 10 per unit area in the X-Y plane decreases. As a result, an area of the channels per unit area (a channel density) decreases, and the ON-resistance of the semiconductor device 100r increases.

In the semiconductor device 100 according to the embodiment, the first conductive layer 21 is provided inside the n⁻-type semiconductor region 1 with the first insulating layer 21i interposed. The first conductive layer 21 is separated from the p-type base region 2 and the gate electrode 10 in the Z-direction. Therefore, the arrangement and the structures of the gate electrodes 10 can be optimized regardless of the arrangement and the structures of the first conductive layers 21. For example, as illustrated in FIG. 4, the distance D3 between adjacent gate electrodes 10 can be shorter than the distance D4 between adjacent first conductive layers 21. Thereby, the ON-resistance of the semiconductor device 100 can be reduced while improving the breakdown voltage of the semiconductor device 100.

In order to effectively improve the breakdown voltage of the semiconductor device 100, it is desirable that the distance D1 in the Z-direction between the first conductive layer 21 and the p-type base region 2 is shorter than the distance D2 in the Z-direction between the first conductive layer 21 and the drain electrode 31, as shown in FIG. 4. According to this arrangement, the depletion layer extending from the interface between the first insulating layer 21i and the n⁻-type semiconductor region 1 can easily be connected to the depletion layer extending from the interface between the p-type base region 2 and the n⁻-type semiconductor region 1. As a result, the breakdown voltage of the semiconductor device 100 can be improved.

It is desirable that the second conductive layer 22 includes a second conductive portion 22b. By providing the second conductive portion 22b, the source electrode 32 can be easily connected to the second conductive layer 22. In addition, the electrical resistance of the second conductive layer 22 can be reduced. As a result, a potential of each first conductive layer 21 can be more reliably made equal to a potential of the source electrode 32.

It is desirable that the length L4 in the Y-direction of the first conductive portion 22a is longer than the length L5 in the Y-direction of the first conductive layer 21. Thereby, the electrical resistance of the second conductive layer 22 can be further reduced.

It is desirable that the lower end of the second conductive layer 22 is located below the lower end of the first conductive layer 21. Thereby, the electrical resistance of the second conductive layer 22 can be further reduced.

### (First Modification)

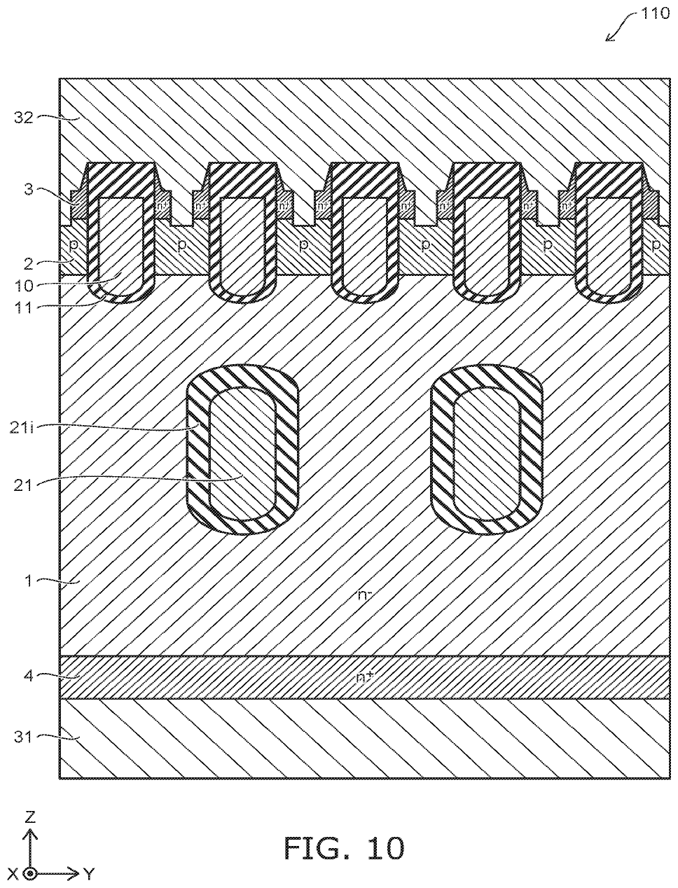

FIG. 10 is a cross-sectional view showing a portion of a semiconductor device according to a first modification of the embodiment.

In the semiconductor device 100 shown in FIG. 1 to FIG. 5, one first conductive layer 21 is located directly below one p-type base region 2. On the other hand, in the semiconductor device 110 shown in FIG. 10, at least a portion of one first conductive layer 21 is located directly below one gate electrode 10. For example, the center of one first conductive layer 21 in the Y-direction is located directly below one gate electrode 10.

According to this arrangement, the flow of carriers from the source electrode 32 to the drain electrode 31 through the channel is less likely to be blocked by the first conductive layer and the first insulating layer 21i. Thereby, the ON-resistance of the semiconductor device 110 can be further reduced.

### (Second Modification)

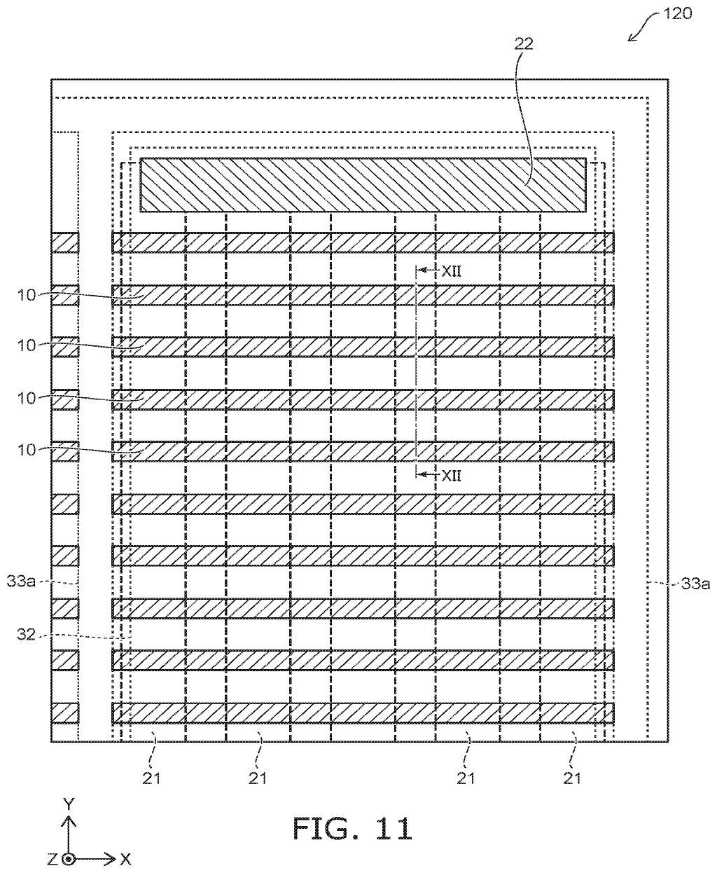

FIG. 11 is a plan view showing a portion of a semiconductor device according to a second modification of the embodiment.

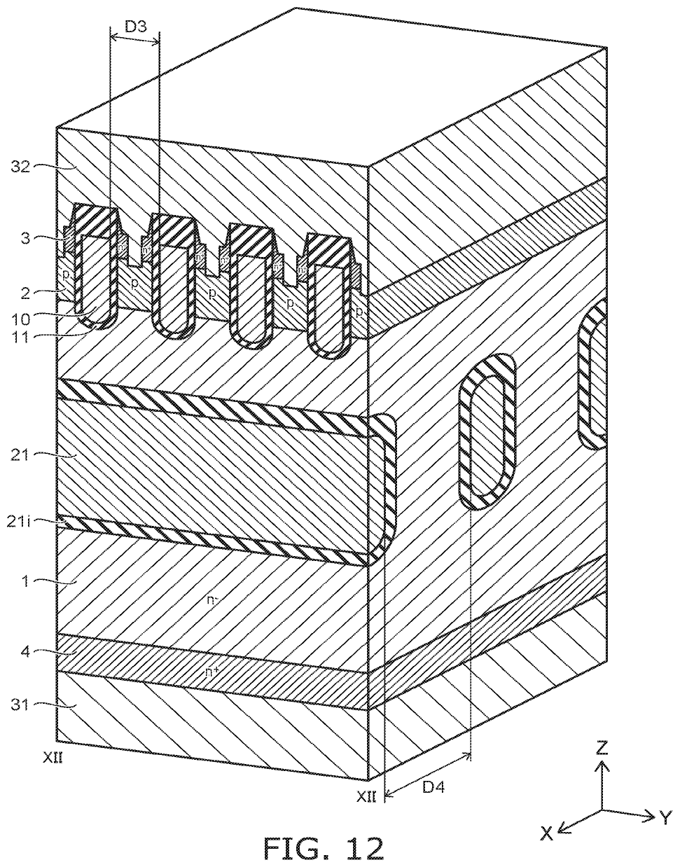

FIG. 12 is a perspective cross-sectional view including the XII-XII cross section of FIG. 11.

In the semiconductor device 100 shown in FIG. 1 to FIG. 5, the first conductive layers 21 are arranged in the Y-direction. In the semiconductor device 120 shown in FIG. 11 and FIG. 12, the first conductive layers 21 are arranged in the X-direction. In other words, an arrangement direction of the first conductive layers 21 intersects an arrangement direction of the gate electrodes 10. An extending direction of each first conductive layer 21 intersects an extending direction of each gate electrode 10.

As shown in FIG. 11, the end in the Y-direction of each first conductive layer 21 is connected to the second conductive layer 22. In the semiconductor device 120, the third conductive layer 23 is not provided. For example, as shown in FIG. 12, the distance D3 between the adjacent gate electrodes 10 is shorter than the distance D4 between the adjacent first conductive layers 21.

In the semiconductor device 120 according to the second modification, the arrangement direction of the first conductive layers 21 intersects the arrangement direction of the gate electrodes 10. According to this structure, in the manufacturing processes of the semiconductor device 120, a direction of warp of the semiconductor substrate when the first conductive layers 21 are formed can be different from a direction of warp of the semiconductor substrate when the gate electrodes 10 are formed. For example, in the manufacturing processes of the semiconductor device 120, the largeness of warp in a specific direction of the semiconductor substrate can be reduced. Therefore, according to the second modification, the yield of the semiconductor device 120 can be improved.

### (Third Modification)

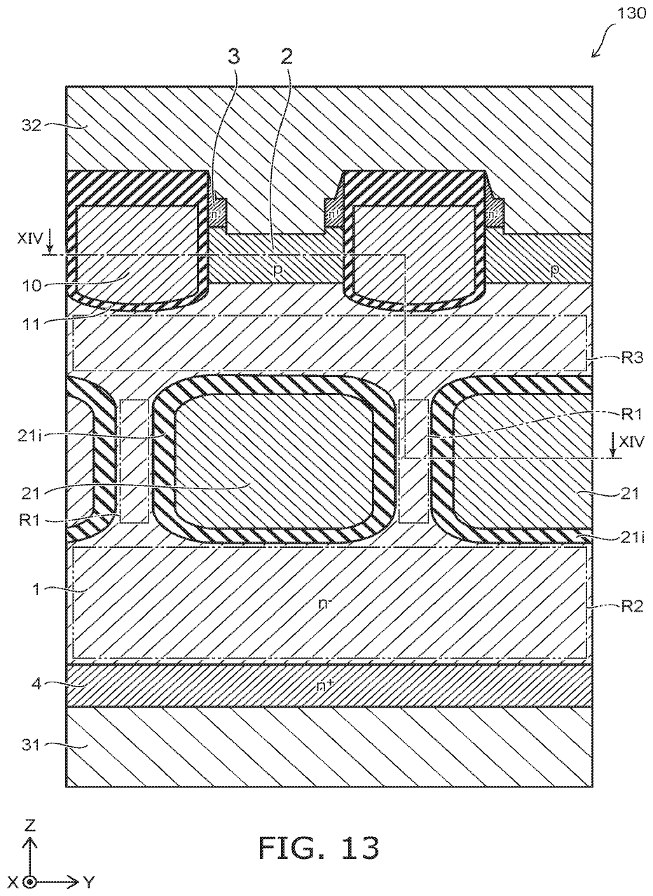

FIG. 13 is a cross-sectional view showing a portion of a semiconductor device according to a third modification of the embodiment.

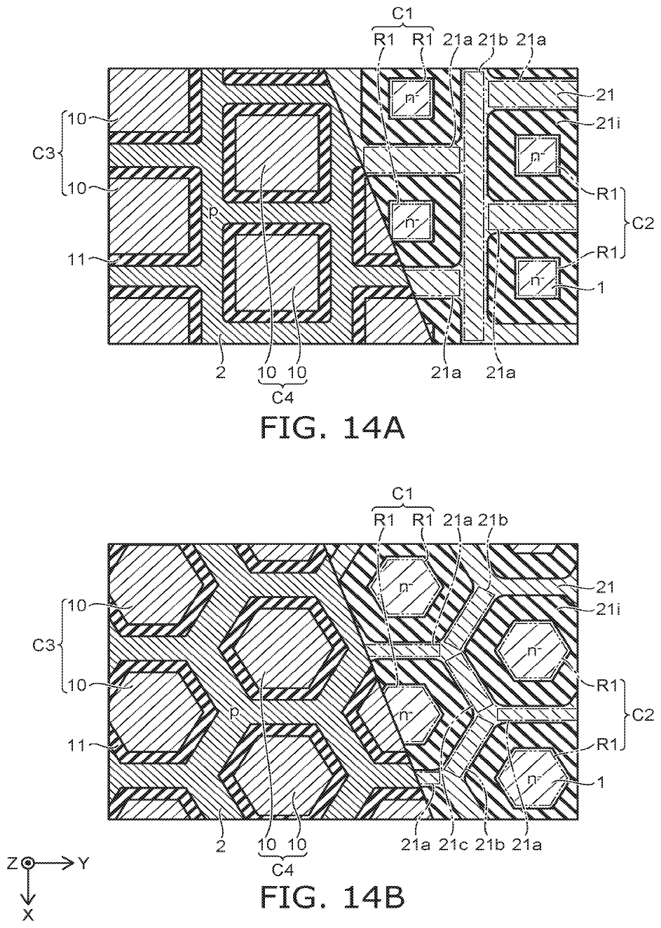

FIG. 14A is an example of a plan view including the XIV-XIV cross section of FIG. 13. FIG. 14B is another example of a plan view including the XIV-XIV cross section of FIG. 13.

The semiconductor device 130 shown in FIG. 13, FIG. 14A, and FIG. 14B is different from the semiconductor devices 100 to 120, for example, in the shapes and the arrangements of the gate electrodes 10 and the first conductive layers 21.

For example, as shown in FIG. 14A, the first conductive layer 21 includes a first extending portion 21a and a second extending portion 21b. The first extending portion 21a extends along one direction (first extending direction) parallel to the X-Y plane. The second extending portion 21b extends along another direction (second extending direction) parallel to the X-Y plane and intersecting the first extending direction.

In the example of FIG. 14A, the first extending direction is perpendicular to the second extending direction. The end of the first extending portion 21a in the first extending direction is connected to the second extending portion 21b.

In the example of FIG. 14B, the first conductive layer 21 further includes a third extending portion 21c. The second extending direction is not perpendicular to the first extending direction. The third extending portion 21c extends along one direction (third extending direction) parallel to the X-Y plane. The third extending direction intersects the first extending direction and the second extending direction. The end of the first extending portion 21a in the first extending direction is connected to the end of the second extending portion 21b in the second extending direction and the end of the third extending portion 21c in the third extending direction.

As shown in FIG. 13, the n⁻-type semiconductor region 1 includes a plurality of first regions R1, a second region R2, and a third region R3. The first regions R1 are surrounded by the first conductive layer 21 along the X-Y plane. The first regions R1 are provided between the second region R2 and the third region R3 in the Z-direction. The second region R2 is provided between the drain electrode 31 and the first regions R1 in the Z-direction. The third region R3 is provided between the first regions R1 and the p-type base region 2 and between the first regions R1 and the gate electrodes 10 in the Z-direction.

As shown in FIG. 14A and FIG. 14B, a portion of the first regions R1 are arranged along the X-direction to form a column C1. Another portion of the first regions R1 are arranged along the X-direction to form a column C2. A center position in the X-direction of the first region R1 included in the column C1 is different from a center position in the X-direction of the first region R1 included in the column C2. For example, a plurality of columns C1 and a plurality of columns C2 are provided alternately in the Y-direction.

Similarly, a portion of the gate electrodes 10 are arranged along the X-direction to form a column C3. Another portion of the gate electrodes 10 are arranged along the X-direction to form a column C4. A center position in the X-direction of the gate electrode 10 included in column C3 is different from a center position in the X-direction of the gate electrode 10 included in the column C4. For example, a plurality of columns C3 and a plurality of columns C4 are provided alternately in the Y-direction.

In the example of FIG. 14A, the shape of each first region R1 and the shape of each gate electrode 10 are rectangular in the X-Y cross section. In the example of FIG. 14B, the shape of each first region R1 and the shape of each gate electrode 10 are hexagonal in the X-Y cross section. The shape of each first region R1 and each gate electrode 10 in the X-Y cross section are arbitrary.

Thus, in the semiconductor device 130 according to the third modification shown in FIG. 13, FIG. 14A, and FIG. 14B, the column of the gate electrodes 10 arranged in the X-direction is multiply provided in the Y-direction. According to this structure, the channel is formed in the p-type base region 2 around each gate electrode 10. Therefore, in the semiconductor device 130, the channel density can be increased as compared with the semiconductor devices 100 to 120.

A portion of the n⁻-type semiconductor region 1 (the third region R3) is provided between the first conductive layer 21 and the p-type base region 2 and between the first conductive layer 21 and the gate electrodes 10, similar to the semiconductor devices 100 to 120. Therefore, the arrangement and the structures of the gate electrodes 10 can be optimized regardless of the arrangement and the structure of the first conductive layer 21.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region provided on the first electrode, the first semiconductor region being of a first conductivity type and being electrically connected to the first electrode;
a second semiconductor region provided on the first semiconductor region, the second semiconductor region being of a second conductivity type;
a third semiconductor region selectively provided on the second semiconductor region, the third semiconductor region being of the first conductivity type;
a gate electrode opposing, with a gate insulating portion interposed, a portion of the first semiconductor region, the second semiconductor region, and the third semiconductor region in a first direction perpendicular to a second direction, the second direction being from the first semiconductor region toward the second semiconductor region;
a first conductive layer provided inside the first semiconductor region with a first insulating layer interposed, another portion of the first semiconductor region being provided between the first conductive layer and the second semiconductor region and between the first conductive layer and the gate electrode; and
a second electrode provided on the second semiconductor region, the third semiconductor region, and the gate electrode, the second electrode being electrically connected to the second semiconductor region, the third semiconductor region, and the first conductive layer.

2. The device according to claim 1, wherein a distance in the second direction between the first conductive layer and the second semiconductor region is shorter than a distance in the second direction between the first conductive layer and the first electrode.

3. The device according to claim 1, wherein
the gate electrode and the first conductive layer extend along a third direction perpendicular to the first direction and the second direction, and
at least a portion of the first conductive layer is located directly below the gate electrode.

4. The device according to claim 1, comprising:
a plurality of the gate electrodes separated from each other in the first direction; and
a plurality of the first conductive layers separated from each other in the first direction,
a distance in the first direction between adjacent ones of the plurality of gate electrodes being shorter than a distance in the first direction between adjacent ones of the plurality of first conductive layers.

5. The device according to claim 1, comprising:
a plurality of the gate electrodes separated from each other in the first direction; and
a plurality of the first conductive layers separated from each other in a third direction perpendicular to the second direction and intersecting the first direction,
a distance in the first direction between adjacent ones of the plurality of gate electrodes being shorter than a distance in the third direction between adjacent ones of the plurality of first conductive layers.

6. The device according to claim 1, further comprising a second conductive layer provided inside the first semiconductor region with a second insulating layer interposed,
the second conductive layer being electrically connected to the first conductive layer,
a length in the second direction of the second conductive layer being longer than a length in the second direction of the first conductive layer,
the second conductive layer being in contact with the second electrode.

7. The device according to claim 6, wherein
the second conductive layer includes a first conductive portion and a second conductive portion provided on the first conductive portion,
a length in the first direction of the second conductive portion is longer than a length in the first direction of the first conductive portion, and
the second conductive portion is in contact with the second electrode.

8. The device according to claim 7, wherein a length in the first direction of the first conductive portion is longer than a length in the first direction of the first conductive layer.

9. The device according to claim 6, wherein a lower end of the second conductive layer is located lower than a lower end of the first conductive layer.
